(19) United States
(12) Patent Application Publication
(10) Pub. No.: US 2017/0020000 A1
(43) Pub. Date: Jan. 19, 2017

(54) COMPONENT-MOUNTED BOARD, METHOD OF MANUFACTURING COMPONENT-MOUNTED BOARD AND COMPONENT-EMBEDDED BOARD

(71) Applicant: FUJITSU LIMITED, Kawasaki-shi (JP)

(72) Inventors: TAKATOYO YAMAKAMI, Nagano (JP); Naoki Ishikawa, Nagano (JP); Kimio Nakamura, Suzaka (JP); Kenji Iida, Nagano (JP); Hiromitsu Kobayashi, Nagano (JP); Kei Fukui, Iizuna (JP)

(73) Assignee: FUJITSU LIMITED, Kawasaki-shi (JP)

(21) Appl. No.: 15/207,027

(22) Filed: Jul. 11, 2016

(30) Foreign Application Priority Data
Jul. 17, 2015 (JP) 2015-143247

(51) Int. Cl. H05K 1/18; H01L 23/498; H05K 3/46; H05K 1/11; H05K 3/30; H05K 3/40; H01L 23/538; H01L 21/48

(52) U.S. Cl. CPC H05K 1/185; H01L 23/5389; H01L 23/49827; H01L 21/486; H05K 1/112; H05K 1/116; H05K 3/305; H05K 3/4053; H05K 3/4611; H05K 2201/10636; H05K 2201/10977; H05K 2201/10015

(57) ABSTRACT

A component-mounted board includes: a substrate; an electronic component disposed over the substrate; and a conductive via formed in the substrate to be in contact with a bottom surface and a side surface of an electrode of the electronic component in a state where the electronic component is disposed over the substrate.

### CROSS-REFERENCE TO RELATED APPLICATION

This application is based upon and claims the benefit of priority of the prior Japanese Patent Application No. 2015-143247 filed on Jul. 17, 2015, the entire contents of which are incorporated herein by reference.

### FIELD

The embodiments discussed herein are related to a component-mounted board, a component-embedded board, and a method of manufacturing the component-mounted board.

### BACKGROUND

The following technologies have been known as technologies related to a component-mounted board having an electronic component mounted on a component-mounting surface of a substrate.

For example, there is known a technology of configuring a terminal formed on a component-mounting surface of a laminated body formed by laminating a plurality of ceramic layers by an exposed end face of a via-hole conductor extending from the inside of the laminated body to the component-mounting surface. The terminal is used for connection to a component to be mounted on the component-mounting surface of the laminated body.

In addition, there is known a technology of integrally interconnecting an electrode formed on a wiring board and an electrode formed on an electronic component by a conductive material in a resin mold type module.

Also, there is known a technology of forming conductive via by filling a conductive paste in a through hole for a via hole, and connecting a chip component to an electrode connected to the conductive via.

There is known a laminated wiring board including: a first board including an insulating layer having a conductor circuit formed thereon and an adhesive layer, the first board being formed by forming a conductive material within each of a plurality of via holes penetrating the layers; and an electronic component electrically connected to the corresponding conductor circuit through an electrode connected to the corresponding conductive material. In the laminated wiring board, two or more conductive materials, which are electrically conducted with one electrode of the electronic component, are in contact with the corresponding electrode only inside one surface of the corresponding electrode.

A component-embedded board, in which electronic components such as a semiconductor integrated circuit (IC) and a passive component are buried in a printed circuit board, is frequently applied to, in particular, a mobile terminal or the like in which high density mounting is highly requested. In the future, it is expected that the component-embedded boards will be more widely applied to a server, a main board, and an in-vehicle engine control unit (ECU) as means for increasing a transmission speed and achieving a high-density mounting, and the application pace will be accelerated.

As a method of bonding an electrode of an electronic component embedded in a component-embedded board to a wiring or pad formed within the component-embedded board, for example, solder bonding, via-plating bonding and via-paste bonding have been devised. Among the three methods described above, the “via-paste bonding” that is advantageous in terms of a bonding reliability and a cost is attracting attention.

A component-embedded board obtained by via-paste bonding is configured by laminating a plurality of boards including a component-mounted board mounted with an electronic component, through adhesive layers. The component-mounted board is manufactured by, for example, the following procedure. A conductive pad is formed on the rear surface opposite to a component-mounting surface of a substrate, and a via hole extending from the component-mounting surface of the substrate to the corresponding pad is formed. Then, a conductive via is formed by filling a conductive paste in the via hole. Then, an electronic component that includes an electrode such as, for example, a chip capacitor, is mounted on the component-mounting surface of the substrate. Here, positioning of the electronic component is performed such that the bottom surface of the electrode of the electronic component is in contact with the upper end of the conductive via. Then, the conductive paste is cured by a heat treatment. Accordingly, the electrode of the electronic component is bonded to the conductive via, and is electrically connected to the pad formed on the rear surface of the substrate through the conductive via.

However, the diameter of the conductive via is small, which ranges from about 10 μm to 200 μm. Further, the electronic component is in contact with the conductive via only on the bottom surface. Accordingly, the adhesion between an uncured conductive via and the electronic component may be low, the electronic component may be misaligned from a mounting position on the substrate when or after the electronic component is mounted, or the electronic component may be scattered

Even if the electronic component could be mounted at a proper position, the electronic component may be pulled to one of two electrodes provided in the electronic component due to the contraction of the conductive paste when the conductive paste is cured. In this case as well, the electronic component may be misaligned from the proper mounting position.

When the entire upper end of the conductive via is blocked by the electrode of the electronic component, a part of a resin contained in the conductive paste is hardly released to the outside in the heat treatment for curing the conductive paste. When the release of the resin contained in the conductive paste to the outside is suppressed, a resin segregation layer is formed within the conductive via, and leads to a characteristic deterioration or a bonding strength degradation. In particular, when the resin segregation layer is formed around a bonding interface to the electrode of the electronic component, a crack or a breakage may occur in the conductive via due to stress applied in the process of laminating a plurality of boards including the component-mounted board. That is, when the resin segregation layer is formed within the conductive via, the bonding reliability between the electronic component and the conductive via may be significantly lowered.

The followings are reference documents.
[Document 1] Japanese Laid-open Patent Publication No. 2001-267453,
[Document 2] Japanese Laid-open Patent Publication No. 2006-041071,
[Document 3] Japanese Laid-open Patent Publication No. 2001-284484, and
[Document 4] International Publication Pamphlet No. WO2012/005236.

### SUMMARY

According to an aspect of the invention, a component-mounted board includes: a substrate; an electronic component disposed over the substrate; and a conductive via formed in the substrate to be in contact with a bottom surface and a side surface of an electrode of the electronic component in a state where the electronic component is disposed over the substrate.

The object and advantages of the invention will be realized and attained by means of the elements and combinations particularly pointed out in the claims.

It is to be understood that both the foregoing general description and the following detailed description are exemplary and explanatory and are not restirctive of the invention, as claimed.

### BRIEF DESCRIPTION OF DRAWINGS

FIG. 1A is a sectional view illustrating a manufacturing process of a component-mounted board and a component-embedded board according to a comparative example;

FIG. 1B is a sectional view illustrating a manufacturing process of the component-mounted board and the component-embedded board according to the comparative example;

FIG. 1C is a sectional view illustrating a manufacturing process of the component-mounted board and the component-embedded board according to the comparative example;

FIG. 1D is a sectional view illustrating a manufacturing process of the component-mounted board and the component-embedded board according to the comparative example;

FIG. 1E is a sectional view illustrating a manufacturing process of the component-mounted board and the component-embedded board according to the comparative example;

FIG. 2A is a plan view illustrating the vicinity of an electronic component of the component-mounted board according to the comparative example when viewed from a component-mounting surface side;

FIG. 2B is a sectional view taken along line 2B-2B of FIG. 2A;

FIG. 3 is a sectional view illustrating the component-mounted board according to the comparative example;

FIG. 4A is a plan view illustrating a part of a component-mounted board according to an exemplary aspect of the disclosure when viewed from a component-mounting surface side;

FIG. 4B is a sectional view taken along line 4B-4B of FIG. 4A;

FIG. 5 is a sectional view illustrating a configuration of a component-embedded board, according to the exemplary aspect of the disclosure;

FIG. 6A is a plan view illustrating a part of a component-mounted board according to another exemplary aspect of the disclosure, when viewed from a component-mounting surface side;

FIG. 6B is a plan view illustrating a part of a component-mounted board according to another exemplary aspect of the disclosure, when viewed from a component-mounting surface side;

FIG. 7 is a plan view illustrating a part of a component-mounted board according to another exemplary aspect of the disclosure, when viewed from a component-mounting surface side;

FIG. 8A is a plan view illustrating a part of a component-mounted board according to another exemplary aspect of the disclosure, when viewed from a component-mounting surface side;

FIG. 8B is a plan view illustrating a part of a component-mounted board according to another exemplary aspect of the disclosure, when viewed from a component-mounting surface side;

FIG. 9 is a plan view illustrating a part of a component-mounted board according to another exemplary aspect of the disclosure, when viewed from a component-mounting surface side;

FIG. 10A is a sectional view illustrating a manufacturing process of a component-mounted board according to an exemplary embodiment of the disclosure;

FIG. 10B is a sectional view illustrating a manufacturing process of the component-mounted board according to the exemplary embodiment of the disclosure;

FIG. 10C is a sectional view illustrating a manufacturing process of the component-mounted board according to the exemplary embodiment of the disclosure;

FIG. 10D is a sectional view illustrating a manufacturing process of the component-mounted board according to the exemplary embodiment of the disclosure;

FIG. 10E is a sectional view illustrating a manufacturing process of the component-mounted board according to the exemplary embodiment of the disclosure;

FIG. 10F is a sectional view illustrating a manufacturing process of the component-mounted board according to the exemplary embodiment of the disclosure;

FIG. 11 is a view illustrating the vicinity of a conductive via 30 according to the exemplary embodiment of the disclosure, in an enlarged scale;

FIG. 12A is a plan view illustrating a relative positional relationship between an electronic component and a conductive via according to the exemplary embodiment of the disclosure;

FIG. 12B is a plan view illustrating a relative positional relationship between an electronic component and a conductive via according to the exemplary embodiment of the disclosure;

FIG. 12C is a plan view illustrating a relative positional relationship between an electronic component and a conductive via according to the exemplary embodiment of the disclosure;

FIG. 13 is a photograph captured on a section in the vicinity of a bonding portion between an electrode of the electronic component and the conductive via according to the exemplary embodiment of the disclosure;

FIG. 14A is a plan view illustrating a relative positional relationship between an electronic component and a conductive via according to the comparative example;

FIG. 14B is a plan view illustrating a relative positional relationship between an electronic component and a conductive via according to the comparative example;

FIG. 14C is a plan view illustrating a relative positional relationship between an electronic component and a conductive via according to the comparative example;

FIG. 15A is a sectional view illustrating a manufacturing process of a component-embedded board according to the exemplary embodiment of the disclosure;

FIG. 15B is a sectional view illustrating a manufacturing process of the component-embedded board according to the exemplary embodiment of the disclosure;

FIG. 15C is a sectional view illustrating a manufacturing process of the component-embedded board according to the exemplary embodiment of the disclosure;

FIG. 16A is a sectional view illustrating a manufacturing process of the component-embedded board according to the exemplary embodiment of the disclosure;

FIG. 16B is a sectional view illustrating a manufacturing process of the component-embedded board according to the exemplary embodiment of the disclosure; and

FIG. 16C is a sectional view illustrating a manufacturing process of the component-embedded board according to the exemplary embodiment of the disclosure;

### DESCRIPTION OF EMBODIMENTS

Hereinafter, descriptions will be made on an example of an exemplary aspect of the disclosure and a comparative example to be compared with the disclosure with reference to the drawings. It is noted that the same or equivalent components and parts in the respective drawings are denoted by the same reference numerals and the redundant descriptions thereof will be omitted as appropriate.

### COMPARATIVE EXAMPLE

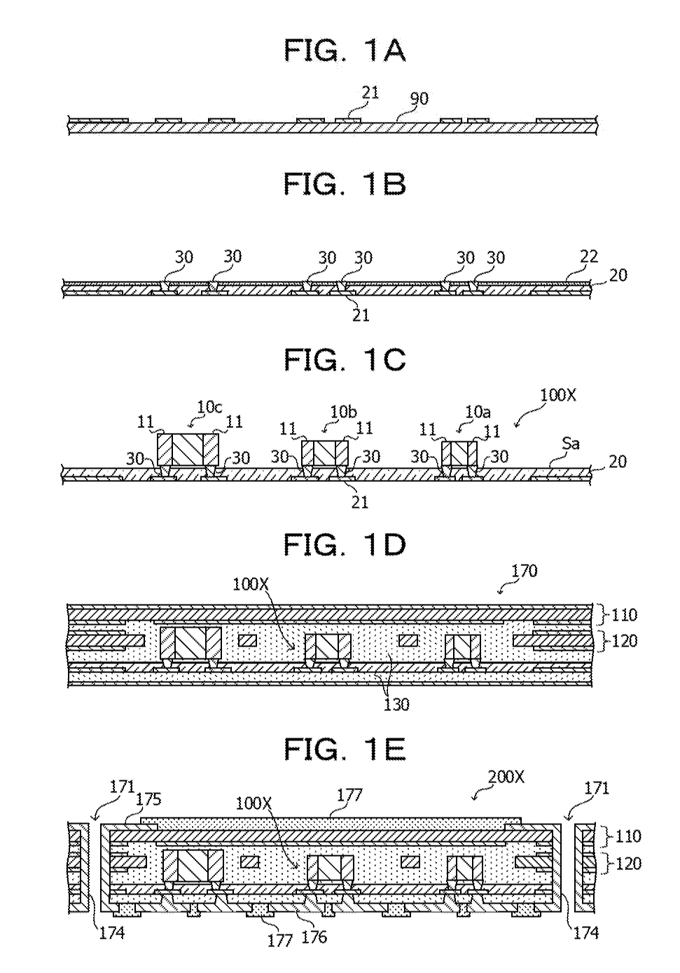

First, descriptions will be made on a component-mounted board and a component-embedded board according to a comparative example. FIGS. 1A to 1E are sectional views illustrating a manufacturing process of a component-mounted board and a component-embedded board according to the comparative example.

First, a conductive film made of a conductor such as, for example, copper is formed on the top surface of a support 90 through, for example, a plating method, and is patterned to form pads 21 (FIG. 1A).

Next, a prepreg that is a material for a substrate 20 that constitutes a component-mounted board is adhered to the top surface of the support 90 to cover the pads 21. Next, a polyethylene terephthalate (PET) film 22 is adhered to the top surface of the substrate 20. Next, via holes extending from the top surface of the PET film 22 to the pads 21 are formed using a laser, and then, the support 90 is released. The pads 21 are released from the support 90, and are transferred to the bottom surface of the substrate 20. Next, a conductive paste is filled in the via holes using a printing method, and conductive vias (via-paste) 30 are formed (FIG. 1B).

Next, the PET film 22 is released, and then, electronic components 10a, 10b, and 10c are mounted on a component-mounting surface Sa of the substrate 20, using a component mounter. Each of the electronic components 10a, 10b, and 10c may be, for example, a chip capacitor having electrodes 11, a chip resistor, a chip inductor, or a semiconductor chip. Then, the conductive paste that constitutes the conductive vias 30 is cured by a heat treatment. Accordingly, the electrodes 11 of the respective electronic components 10a, 10b, and 10c are bonded to the conductive vias 30, and are electrically connected to the pads 21 through the conductive vias 30. Through the above-described steps, a component-mounted board 100X is completed (FIG. 1C).

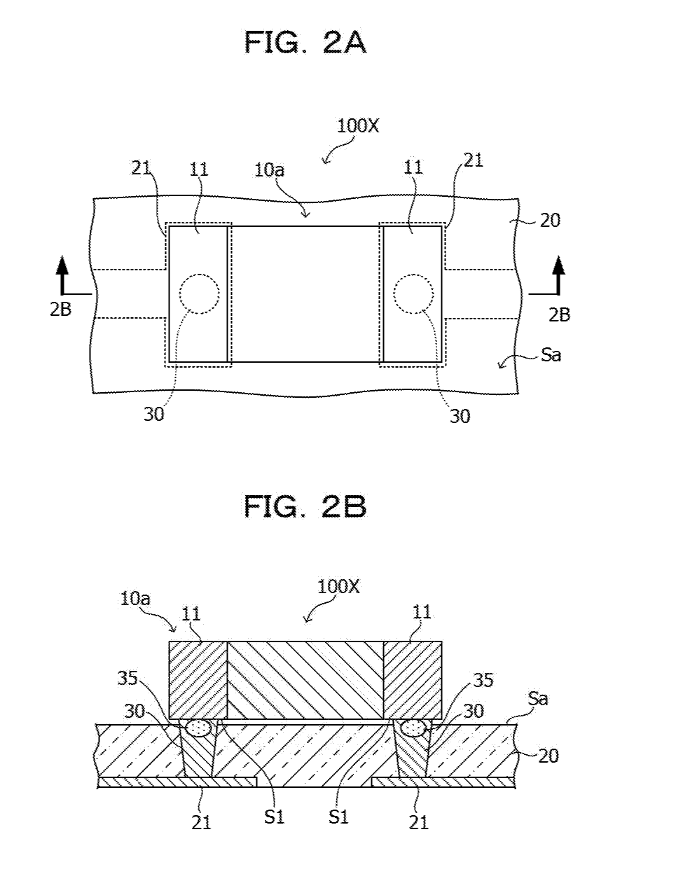

FIG. 2A is a plan view illustrating the vicinity of an electronic component 10a of the component-mounted board 100X according to the comparative example when viewed from the component-mounting surface Sa side, and FIG. 2B is a sectional view taken along line 2B-2B of FIG. 2A. The electronic component 10a is mounted on the substrate 20 such that the bottom surface S1 of the electrode 11 faces the component-mounting surface Sa of the substrate 20 and covers the upper end of the conductive via 30. The other electronic components 10b and 10c are also mounted on the substrate 20 in the same manner as the electronic component 10a.

The component-embedded board including the component-mounted board 100X as a part of a constituent element thereof is manufactured as follows.

The component-mounted board 100X and other boards 110 and 120 are laminated through adhesive layers 130 such as prepregs to form a laminated body 170 (FIG. 1D).

Then, a through hole 171 is formed through the laminated body 170 in the thickness direction. Then, a through-hole wiring 174 is formed on the inner wall surface of the through hole 171 by a plating method, and a top-side wiring 175, a bottom-side wiring 176, and a solder resist 177 are formed on the top surface, and the bottom surface of the laminated body 170, respectively. Through each of the above-described steps, a component-embedded board 200X having the component-mounted board 100X therein is completed.

According to the configuration and the manufacturing method of the component-mounted board 100X and the component-embedded board 200X according to the comparative example, the following problems may be caused.

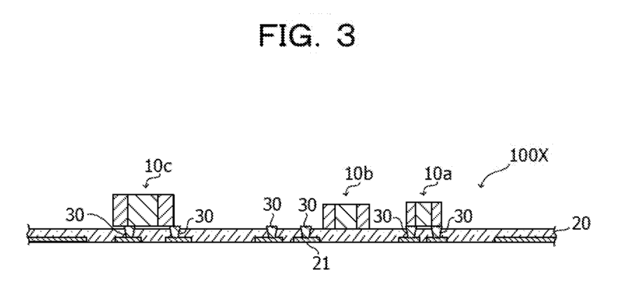

That is, the diameter of the conductive vias 30 formed using a laser is small, which ranges from about 10 μm to 200 μm. Each of the electronic components 10a, 10b and 10c is contact with the conductive vias 30 only at the bottom surface S1. Thus, an adhesion between the conductive vias 30 in an uncured state and each of the electronic components 10a, 10b and 10c is low. Accordingly, as illustrated in FIG. 3, when or after each of the electronic components 10a, 10b and 10c is mounted on the substrate 20, the electronic component may be moved from a mounting position on the substrate and misaligned, or may be scattered. The example illustrated in FIG. 3 illustrates a state where the electronic component 10c is misaligned, and the electronic component 10b is scattered.

Even if each of the electronic components 10a, 10b and 10c was mounted at a proper position, the electronic component may be pulled to one of two electrodes 11 provided in the electronic component due to the contraction of the conductive paste when the conductive paste is cured. Even in this case, each of the electronic components 10a, 10b and 10c may be moved and misaligned from the proper mounting position.

As illustrated in FIG. 2B, when the entire upper end of the conductive via 30 is blocked by the electrode 11 of the electronic component, a part of a resin contained in the conductive paste is hardly released to the outside in the heat treatment for curing the conductive paste. When the release of the resin contained in the conductive paste to the outside is suppressed during the heat treatment, a resin segregation layer 35 may be formed within the conductive via 30, and cause a deterioration of a characteristic or a degradation of a strength. In particular, when the resin segregation layer 35 is formed around a bonding interface to the electrode 11 of the electronic component, a crack or a breakage may occur in the conductive vias 30 due to stress applied at the time of laminating the component-mounted board 100X and the other boards 110 and 120.

<Exemplary Aspect >

Hereinafter, descriptions will be made on a component-mounted board and a component-embedded board according to the exemplary aspect of the disclosure.

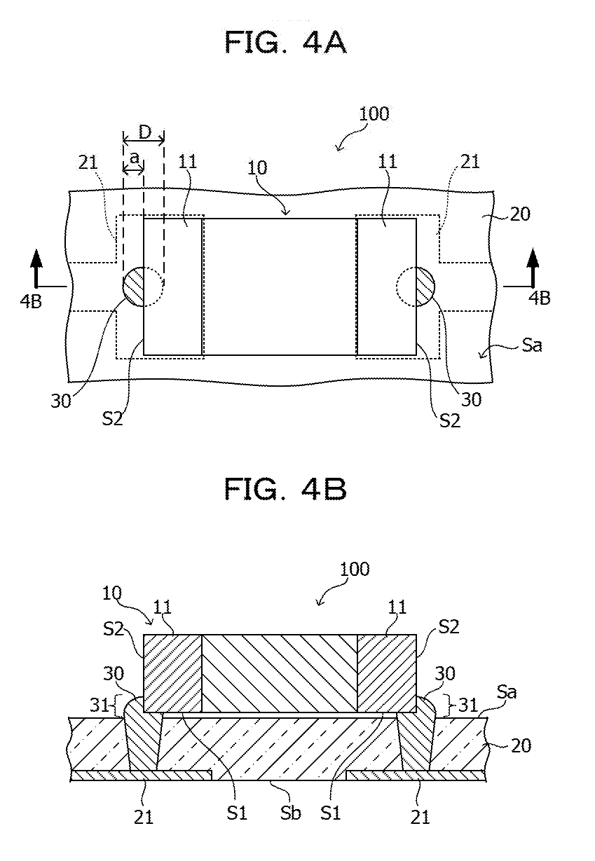

FIG. 4A is a plan view illustrating a part of a component-mounted board 100 according to an exemplary aspect of the disclosure when viewed from a component-mounting surface Sa side, and FIG. 4B is a sectional view taken along line 4B-4B of FIG. 4A. Like the component-mounted board 100X according to the comparative example as described above, the component-mounted board 100 according to the present exemplary aspect includes a substrate 20 composed of an insulator such as a prepreg, and an electronic component 10 mounted on the component-mounting surface Sa of the substrate 20. Also, the component-mounted board 100 includes conductive vias 30 that electrically connect a pair of electrodes 11 provided in the electronic component 10 to pads 21 formed on the rear surface Sb side of the substrate 20. The electronic component 10 has a substantially rectangular parallelepiped shape, and the pair of electrodes 11 are provided at both ends of the rectangular parallelepiped in the longitudinal direction (the horizontal direction in the drawing), and are arranged in the respective surfaces of the rectangular parallelepiped. The electronic component 10 may be, for example, a chip capacitor, a chip resistor, a chip inductor or a semiconductor chip. The electronic component 10 is mounted on the substrate 20 such that the bottom surface S1 of the electrode 11 faces the component-mounting surface Sa of the substrate 20.

In the present exemplary aspect, one conductive via 30 is provided for one (side) electrode 11 of the electronic component 10. Also, in the present exemplary aspect, two conductive vias 30 provided corresponding to one electronic component 10 are arranged along the longitudinal direction of the electronic component 10. Each conductive via 30 forms a protrusion 31 that protrudes from the component-mounting surface Sa of the substrate 20. Each conductive via 30 is disposed on the substrate 20 so as to include a deviation portion deviated from the outer edge of the bottom surface S1 of the electrode 11, and is in contact with the bottom surface S1 of the electrode 11, and a side surface S2 of the electrode 11 that intersects the bottom surface S1. That is, each conductive via 30 is in contact with two different surfaces of the electrode 11.

When the conductive via 30 is disposed at a position partially deviated from the outer edge of the bottom surface S1 of the electrode 11, the corner portion of the electrode 11, which includes the bottom surface S1 and the side surface S2 of the electrode 11, may be buried in the protrusion 31 of the conductive via 30 (the conductive paste) in an uncured state at the time of mounting the electronic component 10. When the contact surfaces between the conductive via 30 and the electrode 11 are formed over the plurality of surfaces of the electrode 11, the adhesion between the conductive via 30 (the conductive paste) and the electrode 11 is improved as compared to a case of the comparative example in which the contact surface between the conductive via 30 and the electrode 11 is formed only on the bottom surface S1 of the electrode 11. Also, the portion of the conductive via 30 in contact with the side surface S2 of the electrode 11 serves as a wall that suppresses a movement of the electronic component 10. Accordingly, when or after the electronic component 10 is mounted, a misalignment or scattering of the electronic component 10 may be suppressed. Also, during the curing of the conductive via 30, the misalignment of the electronic component 10 may also be suppressed. It is desirable that the length a of the conductive via 30, from the outer edge of the bottom surface S1 of the electrode 11, is 30% or more of the diameter D of the conductive via 30 on the component-mounting surface Sa. When the length a of the deviation portion of the conductive via 30 is set to be 30% or more of the diameter D, the contact area between the side surface S2 of the electrode 11 and the conductive via 30 may be secured, and the effect of suppressing a misalignment of the electronic component 10 may be sufficiently achieved.

Also, the conductive via 30 is arranged at a position partially deviated from the outer edge of the bottom surface S1 of the electrode 11, and the upper end of the conductive via 30 is not completely blocked by the electrode 11, but is partially exposed. Thus, when the conductive paste is cured, the resin contained in the conductive paste may be released to the outside, and a resin segregation layer may be suppressed from being formed within the conductive vias 30. Thus, the deterioration of the bonding reliability between the conductive vias 30 and the electronic component 10 may be suppressed.

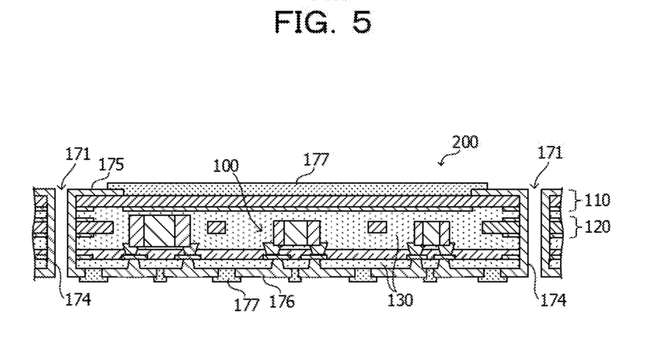

FIG. 5 is a sectional view illustrating a configuration of a component-embedded board 200 according to the exemplary aspect of the disclosure which is configured to include the component-mounted board 100. Like the component-embedded board 200X according to the comparative example, the component-embedded board 200 according to the present exemplary aspect is configured by laminating the component-mounted board 100 and other boards 110 and 120 through adhesive layers 130 such as prepregs. Also, the configuration of the component-embedded board 200 includes a through hole 171, a through-hole wiring 174, a top-side wiring 175, a bottom-side wiring 176, and a solder resist 177.

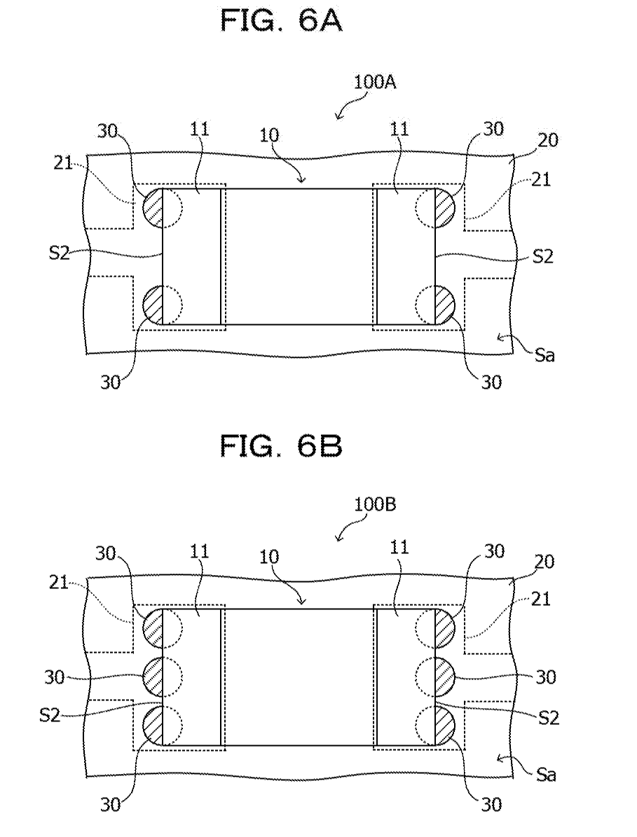

FIGS. 6A, 6B, 7, 8A, 8B and 9 are plan views each illustrating a part of each of component-mounted boards 100A, 100B, 100C, 100D and 100E according to other exemplary aspects of the disclosure, when viewed from a component-mounting surface Sa side.

As illustrated in FIG. 6A, the component-mounted board 100A includes two conductive vias 30 for one (side) electrode 11 of the electronic component 10. That is, in the component-mounted board 100A, the electronic component 10 is bonded to the substrate 20 by a total of four conductive vias 30. Each conductive via 30 is disposed to include a deviation portion deviated from the outer edge of the bottom surface of the electrode 11, and is in contact with a bottom surface of the electrode 11, and a side surface S2 of the electrode 11 that intersects the bottom surface. On the rear surface opposite to the component-mounting surface Sa of the substrate 20, pads 21 are provided. The conductive vias 30 extending from the component-mounting surface Sa in the thickness direction of the substrate 20 are connected to the pads 21. Since each conductive via 30 is arranged at a position deviated from the outer edge of the bottom surface of the electrode 11, the pad 21 has a size larger than the electrode 11 of the electronic component 10.

As illustrated in FIG. 6B, the component-mounted board 100B includes three conductive vias 30 for one (side) electrode 11 of the electronic component 10. That is, in the component-mounted board 100B, the electronic component 10 is bonded to the substrate 20 by a total of six conductive vias 30. Each conductive via 30 is disposed to include a deviation portion deviated from the outer edge of the bottom surface of the electrode 11, and is in contact with a bottom surface of the electrode 11, and a side surface S2 of the electrode 11 that intersects the bottom surface. On the rear surface opposite to the component-mounting surface Sa of the substrate 20, pads 21 are provided. The conductive vias 30 extending from the component-mounting surface Sa in the thickness direction of the substrate 20 are connected to the pads 21. Since each conductive via 30 is arranged at a position deviated from the outer edge of the bottom surface of the electrode 11, the pad 21 has a size larger than the electrode 11 of the electronic component 10.

According to the component-mounted boards 100A and 1008, the misalignment of the electronic component 10 may be suppressed and the deterioration of the bonding reliability between the electronic component 10 and the conductive vias 30 may be suppressed, as in the component-mounted board 100 as described above. Also, when a plurality of conductive vias 30 are provided for one (side) electrode 11 of the electronic component 10, the bonding strength between the electronic component 10 and the substrate 20 may be increased, and the electrical resistance between the electronic component 10 and the pads 21 may be reduced. The number of the conductive vias 30 for one (side) electrode 11 may be properly increased or decreased depending on, for example, the size of the electronic component 10 or the size of the pad 21.

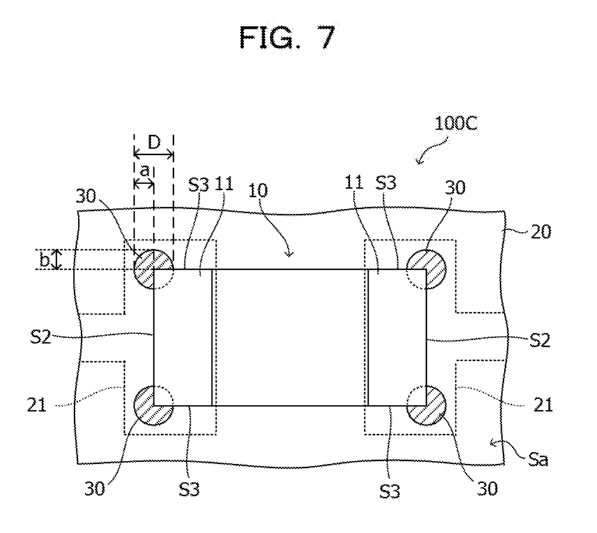

As illustrated in FIG. 7, the component-mounted board 100C includes a plurality of conductive vias 30 arranged at positions corresponding to corner portions of the bottom surface of each electrode 11 of the electronic component 10. Each conductive via 30 is disposed to include a deviation portion deviated from the outer edge of the bottom surface of the electrode 11. More specifically, each conductive via 30 includes a portion deviated from the outer edge of the bottom surface of the electrode 11 in the longitudinal direction of the electronic component 10 (the horizontal direction in the drawing), and a portion deviated in a direction perpendicular to the longitudinal direction of the electronic component 10 (the vertical direction in the drawing). Each of the length a of a portion of each conductive via 30 deviated in the longitudinal direction of the electronic component 10, and the length b of a portion deviated in the direction perpendicular to the longitudinal direction of the electronic component 10, is preferably 30% or more of the diameter D of the conductive via 30 on the component-mounting surface Sa. Each conductive via 30 is in contact with the bottom surface of the electrode 11, a side surface S2 of the electrode 11 that intersects the bottom surface, and a side surface S3 of the electrode 11 that intersects both the bottom surface and the side surface S2. That is, each conductive via 30 is in contact with three different surfaces of the electrode 11. On the rear surface opposite to the component-mounting surface Sa of the substrate 20, pads 21 are provided. The conductive vias 30 extending from the component-mounting surface Sa in the thickness direction of the substrate 20 are connected to the pads 21. Since each conductive via 30 is arranged at a position deviated from the outer edge of the bottom surface of the electrode 11, the pad 21 has a size larger than the electrode 11 of the electronic component 10.

According to the component-mounted board 100C, the misalignment of the electronic component 10 may be suppressed and the deterioration of the bonding reliability between the electronic component 10 and the conductive vias 30 may be suppressed, as in the component-mounted board 100 as described above. Also, when the contact surfaces between the conductive via 30 and the electrode 11 are formed over the three surfaces of the electrode 11, the adhesion between the conductive via 30 (the conductive paste) and the electrode 11 may be further improved, and the effect of suppressing a misalignment of the electronic component 10 may be facilitated.

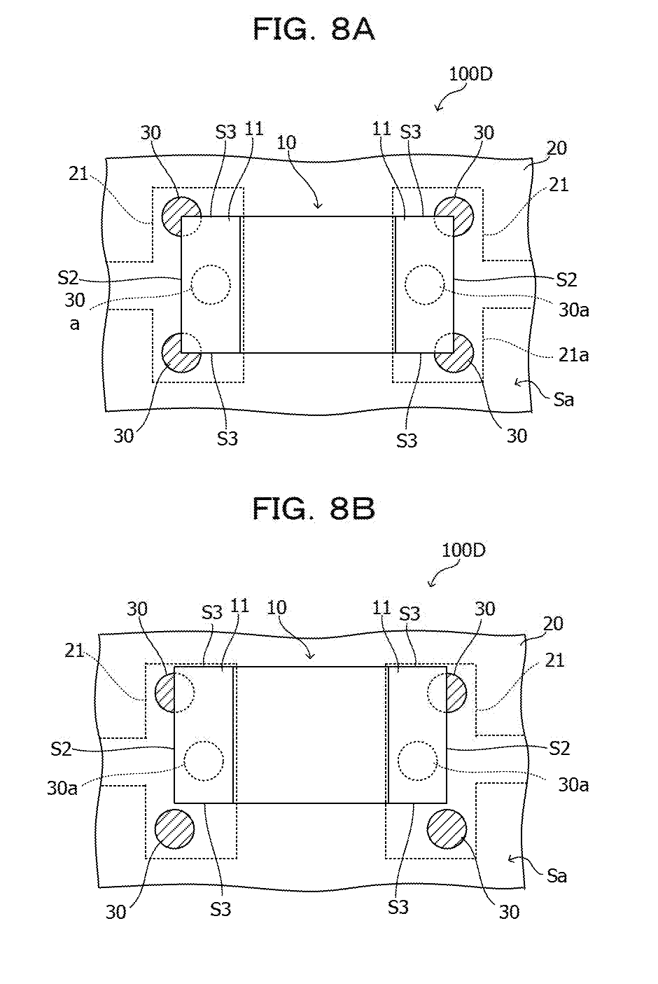

As illustrated in FIG. 8A, the component-mounted board 100D includes a plurality of conductive vias 30 arranged at positions corresponding to corner portions of the bottom surface of each electrode 11 of the electronic component 10, and a conductive via 30a disposed just below the electrode 11 of the electronic component 10. The plurality of conductive vias 30 arranged at positions corresponding to the corner portions of the bottom surface of each electrode 11 of the electronic component 10 are the same as those of the component-mounted board 100C, and thus descriptions thereof will be omitted. Each of the conductive vias 30a is arranged at a position of the substrate 20 not deviated from the outer edge of the bottom surface of the electrode 11 of the electronic component 10. That is, the conductive vias 30a are in contact with the bottom surfaces of the electrodes 11, but are not in contact with side surfaces S2 and S3 of the electrodes 11. When the conductive vias 30a are disposed at positions that are not deviated from the outer edges of the bottom surfaces of the electrodes 11 as described above, an electrical connection between the electronic component 10 and the pads 21 may be maintained by the conductive vias 30a even in a case where a misalignment of the electronic component 10 occurs, as illustrated in FIG. 8B. The conductive vias 30a are desirably arranged at the centers of the bottom surfaces of the electrodes 11, respectively. Accordingly, a possibility that a conduction is secured when a misalignment of the electronic component 10 occurs may be further enhanced. Also, in the present exemplary aspect, it has been described that one conductive via 30a is provided for one (side) electrode 11, but for one (side) electrode 11, two or more conductive vias may be provided at positions not deviated from the outer edge of the bottom surface of the electrode 11.

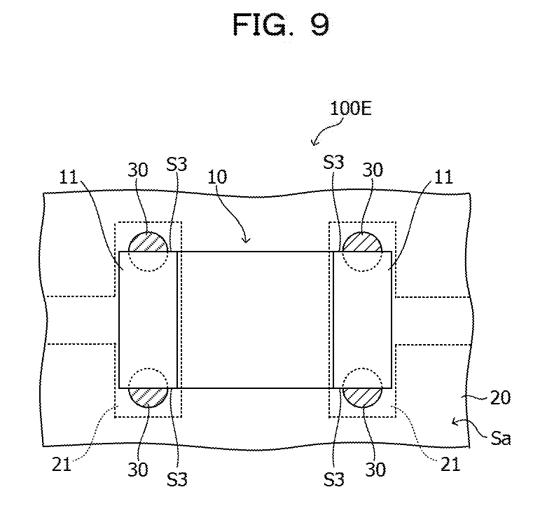

As illustrated in FIG. 9, the component-mounted board 100E includes two conductive vias 30 for one (side) electrode 11 of the electronic component 10. That is, in the component-mounted board 100E, the electronic component 10 is bonded to the substrate 20 by a total of four conductive vias 30. Each conductive via 30 is disposed to include a deviation portion deviated from the outer edge of the bottom surface of the electrode 11, and is in contact with the bottom surface of the electrode 11, and a side surface S3 of the electrode 11 which intersects the bottom surface. That is, in the component-mounted board 100E, the side surface S3 of the electrode 11 in contact with the conductive via 30 is different from the side surface S2 of the electrode 11 in contact with the conductive via 30 in the component-mounted board 100A (see FIG. 6A). On the rear surface opposite to the component-mounting surface Sa of the substrate 20, pads 21 are provided. The conductive vias 30 extending from the component-mounting surface Sa in the thickness direction of the substrate 20 are connected to the pads 21. Since each conductive via 30 is arranged at a position deviated from the outer edge of the bottom surface of the electrode 11, the pad 21 has a size larger than the electrode 11 of the electronic component 10.

According to the component-mounted board 100E, the misalignment of the electronic component 10 may be suppressed and the deterioration of the bonding reliability between the electronic component 10 and the conductive vias 30 may be suppressed, as in the component-mounted board 100 as described above. Also, when a plurality of conductive vias 30 are provided for one (side) electrode 11 of the electronic component 10, the bonding strength between the electronic component 10 and the substrate 20 may be increased, and the electrical resistance between the electronic component 10 and the pads 21 may be reduced. The number of the conductive vias 30 for one (side) electrode 11 may be properly increased or decreased depending on, for example, the size of the electronic component 10 or the size of the pad 21.

Using the component-mounted boards 100A to 100E described above, the component-embedded board may be configured. The arrangements of the conductive vias 30 in the component-mounted boards 100A to 100E may be properly combined. For example, the conductive vias 30a arranged not to be deviated from the outer edges of the bottom surfaces of the electrodes 11 may be applied to the component-mounted boards 100A, 100B, 100C, and 100E.

### Exemplary Embodiment

A component-mounted board according to the exemplary aspect of the disclosure was manufactured, and an evaluation on bonding between electrodes of an electronic component and conductive vias was performed.

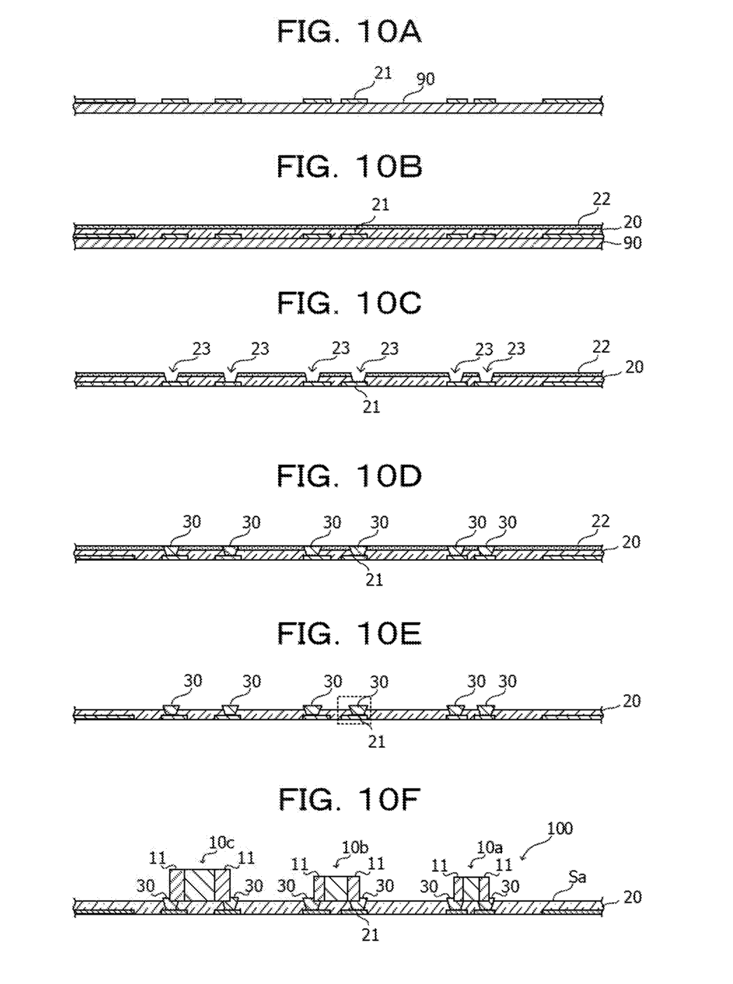

A method of manufacturing the component-mounted board according to the exemplary embodiment of the disclosure will be described below. FIGS. 10A to 10F are sectional views illustrating a manufacturing process of the component-mounted board according to the exemplary embodiment of the disclosure.

A Cu film is formed by a plating method on the top surface of a support 90 which includes an epoxy resin and has a thickness of about 60 μm, and the Cu film is patterned to form conductive pads 21 (FIG. 10A).

Then, a prepreg with a thickness of about 60 μm, which is a material for a substrate 20 constituting a component-mounted board, was adhered to the top surface of the support 90 to cover the pads 21. Then, a PET film 22 with a thickness of about 38 μm was adhered to the top surface of the substrate 20 (FIG. 10B).

Then, via holes 23 with a diameter of about 150 μm extending from the top surface of the PET film 22 to the pads 21 were formed using a laser. Then, the support 90 was released. The pads 21 were released from the support 90, and were transferred to the rear surface of the substrate 20 (FIG. 10C).

Then, a conductive paste was filled in the via holes 23 using a conventionally known printing method, and conductive vias (via-paste) 30 were formed (FIG. 10D). As the conductive paste, an epoxy-based conductive paste containing Sn as a main conductive material was used.

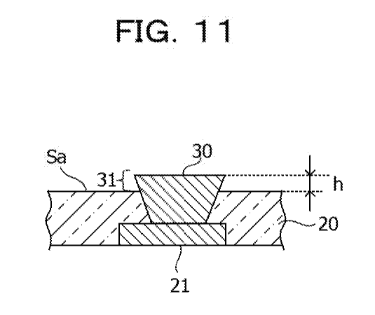

Then, the PET film 22 was released (FIG. 10E). Here, FIG. 11 is a view illustrating the vicinity of a conductive via 30 (a region surrounded by a broken line in FIG. 10E) after the PET film 22 is released, in an enlarged scale. When the PET film 22 is released, the upper end portion of the conductive via 30 protrudes from the component-mounting surface Sa of the substrate 20. The height h of a protrusion 31, that is a portion of the conductive via 30 protruding from the component-mounting surface Sa, is a height (38 μm) corresponding to the thickness of the PET film 22. As described above, when the upper end portion of the conductive via 30 protrudes from the component-mounting surface Sa, an adhesion between the conductive via 30 (conductive paste) and the electronic component to be mounted on the substrate 20 in later steps may be improved. The height h of the protrusion 31 of the conductive via 30 may be adjusted by the thickness of the PET film 22.

Thereafter, the electronic components 10a, 10b, and 10c were mounted on the component-mounting surface Sa of the substrate 20, using a component mounter. As the electronic component 10a, a chip capacitor of 0.6 mm×0.3 mm was used. As the electronic component 10b, a chip capacitor of 1.0 mm×0.5 mm was used. As the electronic component 10c, a chip capacitor of 1.6 mm×0.8 mm was used.

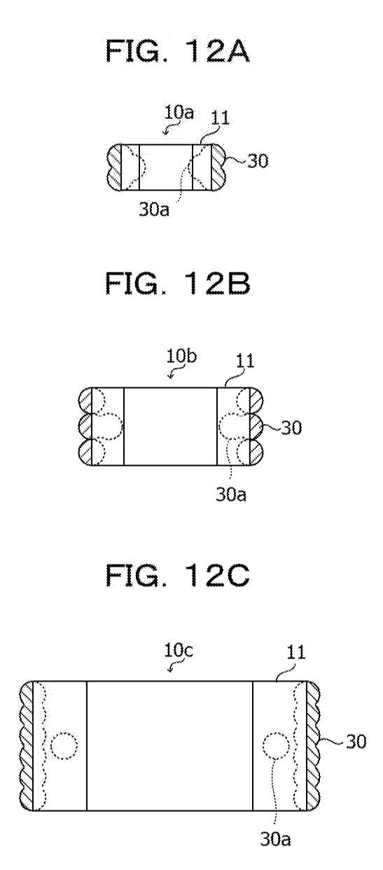

Here, FIGS. 12A, 12B, and 12C are plan views each illustrating a relative positional relationship between a conductive via 30 and each of the electronic components 10a, 10b, and 10c mounted on the component-mounting surface Sa of the substrate 20.

As illustrated in FIG. 12A, two conductive vias 30 were arranged at positions deviated from the outer edge of the bottom surface of each electrode 11 of the electronic component 10a. More specifically, the two conductive vias 30 were arranged such that the center of the two conductive vias 30 is located at the outer edge of the electrode 11. Meanwhile, one conductive via 30a was arranged at a position not deviated from the outer edge of the bottom surface of the electrode 11. More specifically, the conductive via 30a was arranged such that the center of the conductive via 30a is located at the center of the bottom surface of the electrode 11. As described above, a total of three conductive vias are disposed for one (side) electrode 11 of the electronic component 10a.

As illustrated in FIG. 12B, three conductive vias 30 were arranged at positions deviated from the outer edge of the bottom surface of each electrode 11 of the electronic component 10b. More specifically, the three conductive vias 30 were arranged such that the center of the three conductive vias 30 is located at the outer edge of the electrode 11. Meanwhile, one conductive via 30a was arranged at a position not deviated from the outer edge of the bottom surface of the electrode 11. More specifically, the conductive via 30a was arranged such that the center of the conductive via 30a is located at the center of the bottom surface of the electrode 11. As described above, a total of four conductive vias are disposed for one (side) electrode 11 of the electronic component 10b.

As illustrated in FIG. 12C, six conductive vias 30 were arranged at positions deviated from the outer edge of the bottom surface of each electrode 11 of the electronic component 10c. More specifically, the six conductive vias 30 were arranged such that the center of the six conductive vias 30 is located at the outer edge of the electrode 11. Meanwhile, one conductive via 30a was arranged at a position not deviated from the outer edge of the bottom surface of the electrode 11. More specifically, the conductive via 30a was arranged such that the center of the conductive via 30a is located at the center of the bottom surface of the electrode 11. As described above, a total of seven conductive vias are disposed for one (side) electrode 11 of the electronic component 10c.

After the electronic components 10a, 10b, and 10c were mounted on the component-mounting surface Sa of the substrate 20, the conductive paste constituting the conductive vias 30 and 30a was cured by performing a heat treatment at about 200° C. for three (3) hours. Accordingly, the electrodes 11 of the respective electronic components 10a, 10b, and 10c were bonded to the conductive vias 30 and 30a, and were electrically connected to the pads 21 through the conductive vias 30 and 30a. Through the above-described steps, the component-mounted board 100 was completed.

By visually observing the mounting positions of the electronic components 10a, 10b and 10c on the substrate 20, it was confirmed that misalignments of the electronic components 10a, 10b and 10c did not occur.

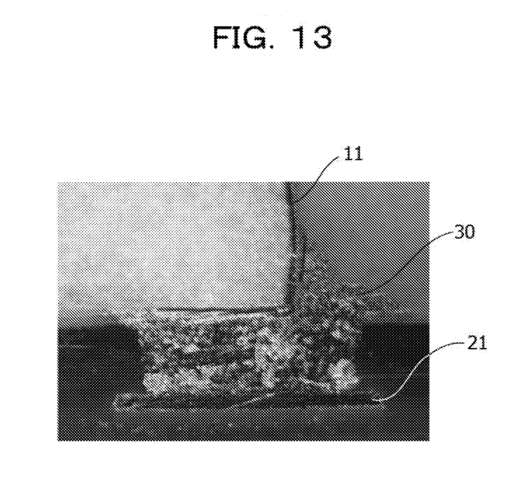

Also, the cross section of the bonding portion between the electrode 11 of the electronic component and the conductive via 30 was observed. FIG. 13 is a photograph captured on a section in the vicinity of the bonding portion between the electrode 11 of the electronic component and the conductive via 30. As illustrated in FIG. 13, it was confirmed that the conductive via 30 is bonded to the bottom surface and the side surface of the electrode 11 of the electronic component. Also, it was confirmed that a resin segregation layer is not formed within the conductive via 30.

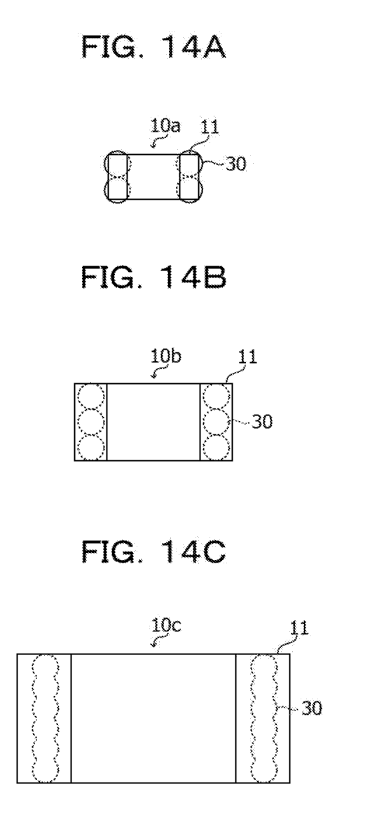

Also, a shear strength of each of the electronic components 10a, 10b, and 10c was measured. A component-mounted board according to a comparative example, which has a different conductive via arrangement from the component-mounted board 100 according to the present exemplary embodiment, was separately manufactured, and their shear strengths were compared to each other. FIGS. 14A, 14B and 14C are plan views each illustrating a relative positional relationship between a conductive via 30 and each of the electronic components 10a, 10b, and 10c on the component-mounted board according to the comparative example. The sizes of the electronic components 10a, 10b, and 10c and the conductive via 30 that constitute the component-mounted board according to the comparative example are the same as those in the component-mounted board 100 according to the exemplary embodiment of the disclosure.

As illustrated in FIG. 14A, in the comparative example, two conductive vias 30 were arranged at positions not deviated from the outer edge of the bottom surface of each electrode 11 of the electronic component 10a. More specifically, the respective conductive vias 30 were arranged such that the center of the two conductive vias 30 is located on the center line of the bottom surface of the electrode 11.

As illustrated in FIG. 14B, in the comparative example, three conductive vias 30 were arranged at positions not deviated from the outer edge of the bottom surface of each electrode 11 of the electronic component 10b. More specifically, the respective conductive vias 30 were arranged such that the center of the three conductive vias 30 is located on the center line of the bottom surface of the electrode 11.

As illustrated in FIG. 14C, in the comparative example, six conductive vias 30 were arranged at positions not deviated from the outer edge of the bottom surface of each electrode 11 of the electronic component 10c. More specifically, the respective conductive vias 30 were arranged such that the center of the six conductive vias 30 is located on the center line of the bottom surface of the electrode 11.

On each of the electronic components 10a, 10b, and 10c of the component-mounted boards according to the present exemplary embodiment and comparative example, a shear strength was measured. The number n of samples of each electronic component was set as 10. In Table 1 below, an average shear strength of each electronic component is noted.

TABLE 1
Average Shear Strength (n = 10)

| | | Present | |
|---|---|---|---|
| | Comparative | Exemplary | Strength |
| | Example | Embodiment | Increase Rate |
| Electronic | 136 g | 185 g | +36% |
| Component 10a | | | |
| Electronic | 189 g | 266 g | +41% |
| Component 10b | | | |
| Electronic | 271 g | 312 g | +15% |
| Component 10c | | | |

In the electronic component 10a (a chip capacitor of 0.6 mm×0.3 mm), when an arrangement of the conductive vias according to the present exemplary embodiment (FIG. 12A) was applied, the average shear strength was 185 g. Meanwhile, when an arrangement of the conductive vias according to the comparative example (FIG. 14A) was applied, the average shear strength was 136 g. That is, by applying the arrangement of conductive vias according to the present exemplary embodiment (FIG. 12A), the shear strength was improved by 36% as compared to that of the comparative example.

In the electronic component 10b (a chip capacitor of 1.0 mm×0.5 mm), when an arrangement of the conductive vias according to the present exemplary embodiment (FIG. 12B) was applied, the average shear strength was 266 g. Meanwhile, when an arrangement of the conductive vias according to the comparative example (FIG. 14B) was applied, the average shear strength was 189 g. That is, by applying the arrangement of conductive vias according to the present exemplary embodiment (FIG. 12B), the shear strength was improved by 41% as compared to that of the comparative example.

In the electronic component 10c (a chip capacitor of 1.6 mm×0.8 mm), when an arrangement of the conductive vias according to the present exemplary embodiment (FIG. 12C) was applied, the average shear strength was 312 g. Meanwhile, when an arrangement of the conductive vias according to the comparative example (FIG. 14C) was applied, the average shear strength was 271 g. That is, by applying the arrangement of conductive vias according to the present exemplary embodiment (FIG. 12C), the shear strength was improved by 15% as compared to that of the comparative example.

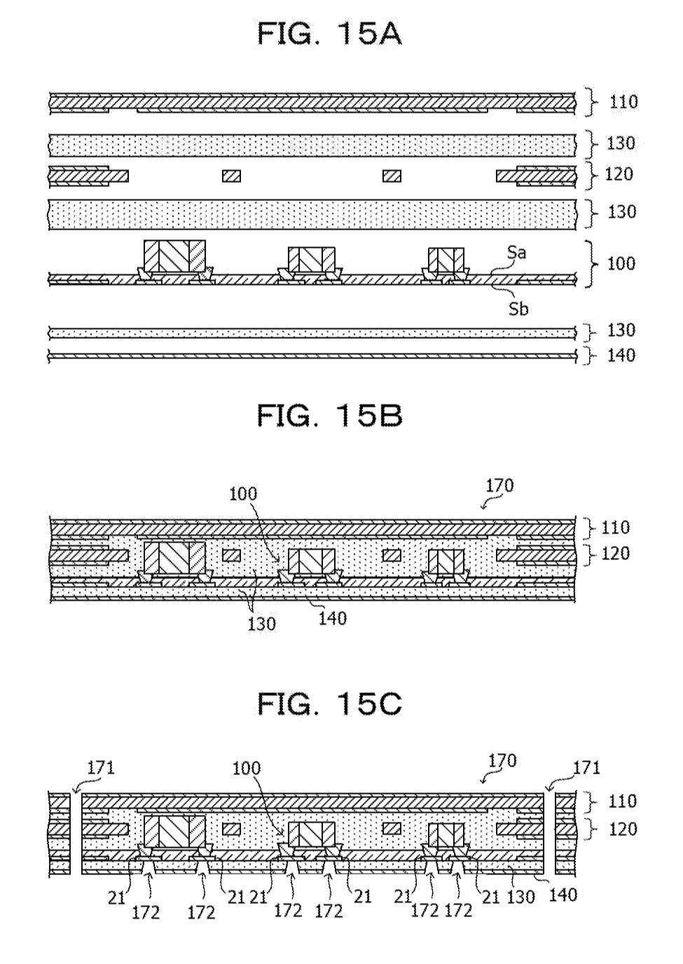

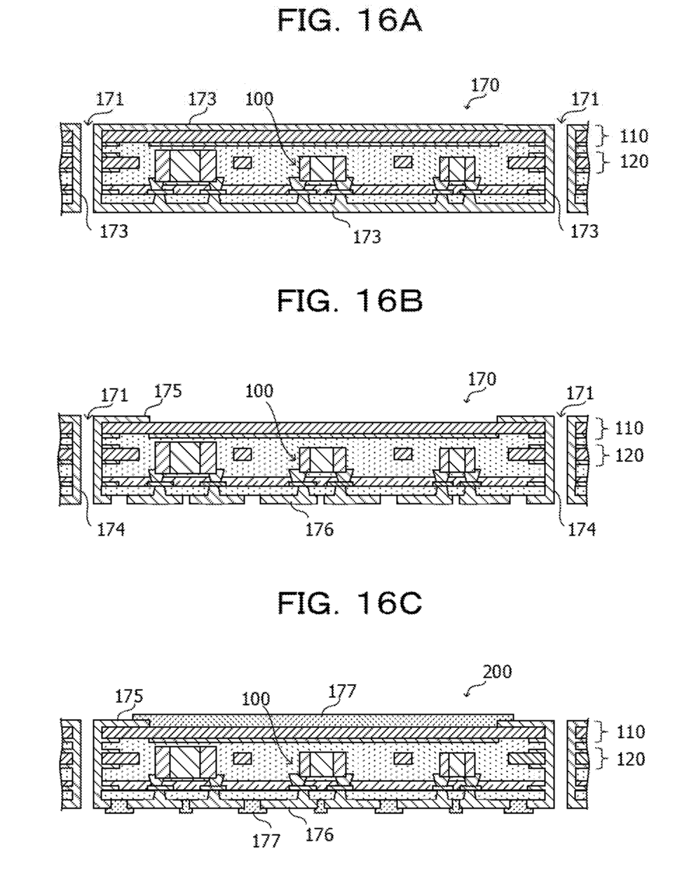

Using the component-mounted board 100 manufactured as described above, according to the exemplary embodiment of the disclosure, a component-embedded board was manufactured. Hereinafter, a method of manufacturing the component-embedded board according to the exemplary embodiment of the disclosure will be described below. FIGS. 15A to 15C, and FIGS. 16A to 16C are sectional views illustrating a manufacturing process of the component-embedded board according to the exemplary embodiment of the disclosure.

At a component-mounting surface Sa side of the component-mounted board 100, boards 110 and 120 formed with wiring patterns were disposed with adhesive layers 130 interposed therebetween, and at the rear surface Sb side of the component-mounted board 100, a conductive film 140 was disposed through an adhesive layer 130. A prepreg was used as the adhesive layer 130, and a copper foil was used as the conductive film 140 (FIG. 15A). The component-mounted board 100, the boards 110 and 120, and the conductive film 140 were stacked with the adhesive layers 130 interposed therebetween, and were applied with a heat and pressure to form a laminated body 170 (FIG. 15B).

Then, a through hole 171 was formed through the laminated body 170 in the thickness direction at a predetermined position of the laminated body 170 by using a drill. Then, via holes 172 were formed to extend from the surface of the conductive film 140 to pads 21 of the component-mounted board 100 using a laser (FIG. 15C).

Next, by a plating method, a copper-plated film 173 was formed on the top and bottom surfaces of the laminated body 170, and the inner wall surface of the through hole 171. The via holes 172 formed in the preceding step (see FIG. 15C) were filled with the copper-plated film 173 (FIG. 16A).

Then, by patterning the plated film 173 using an etching method, a top-side wiring 175 and a bottom-side wiring 176 were formed on the top surface and the bottom surface of the laminated body 170, respectively. Also, a through hole wiring 174 was formed within the through hole 171 (FIG. 16B).

Then, a solder resist 177 was formed to cover a predetermined portion of each of the top-side wiring 175 and the bottom-side wiring 176. Through the above-described respective steps, a component-embedded board 200 was completed (FIG. 16C).

In the completed component-embedded board 200, the conduction between electrodes of each of the electronic components 10a, 10b and 10c was checked through the bottom-side wiring 176. Between the electrodes of each of the electronic components 10a, 10b and 10c, it was confirmed that a good conduction was obtained. That is, even after the above-described respective steps, it was confirmed that a good connection was maintained between the electronic components 10a, 10b and 10c and the conductive vias 30.

The substrate 20 is an example of a substrate in the disclosure. Each of the electronic components 10, 10a, 10b, and 10c is an example of an electronic component in the disclosure. The electrode 11 is an example of an electrode in the disclosure. The bottom surface S1 is an example of a bottom surface according to an exemplary aspect of the disclosure. Each of the side surfaces S2 and S3 is an example of a side surface according to the disclosure. The conductive via 30 is an example of a conductive via in the disclosure. The conductive via 30a is an example of a second conductive via in the disclosure. The pad 21 is an example of a pad in the disclosure. Each of the component-mounted boards 100, 100A, 1006, 100C, 100D, and 100E is an example of a component-mounted board in the disclosure. The component-embedded board 200 is an example of a component-embedded board in the disclosure

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A component-mounted board comprising:
a substrate;
an electronic component disposed over the substrate; and
a conductive via formed in the substrate to be in contact with a bottom surface and a side surface of an electrode of the electronic component in a state where the electronic component is disposed over the substrate.

2. The component-mounted board according to claim 1, wherein the conductive via is arranged at a position corresponding to a corner portion of the bottom surface of the electrode, and is in contact with the bottom surface of the electrode, a first side surface of the electrode that intersects the bottom surface, and a second side surface of the electrode that intersects both the bottom surface and the first side surface.

3. The component-mounted board according to claim 1, wherein the conductive via includes a protrusion protruding from a top surface of the substrate, and the protrusion is in contact with the side surface of the electrode.

4. The component-mounted board according to claim 1, further comprising:
a second conductive via formed in the substrate to be in contact with only the bottom surface of the electrode of the electronic component in a state where the electronic component is disposed over the substrate.

5. The component-mounted board according to claim 1, wherein a length of a portion of the conductive via deviated from an outer edge of the bottom surface of the electrode is 30% or more of a diameter of the conductive via on a component-mounting surface.

6. The component-mounted board according to claim 1, wherein the substrate includes, on a surface side opposite to a component-mounting surface, a conductive pad that is coupled to the conductive via and has a larger size than the electrode.

7. The component-mounted board according to claim 1, wherein the electronic component has a plurality of electrodes, each of which is coupled to the conductive via.

8. The component-mounted board according to claim 1, wherein the conductive via includes a conductive paste.

9. The component-mounted board according to claim 1, wherein the electronic component is a chip capacitor.

10. A method of manufacturing a component-mounted board, the method comprising:
forming a through hole extending over both a region overlapping with an electrode of an electronic component to be mounted, and an outside of the region, in a substrate;
filling a conductive paste within a via hole in a larger amount than an internal volume of the via hole;
arranging the electronic component such that the conductive paste is in contact with a bottom surface and a side surface of the electrode; and
curing the conductive paste.

11. The method according to claim 10, further comprising:
adhering a film over the substrate before forming the through hole; and
releasing the film after filling the conductive paste within the via hole.

12. The method according to claim 10, further comprising:
forming, on a surface side opposite to a surface of the substrate on which the electronic component is mounted, a conductive pad that is coupled to the conductive paste within the through hole, and has a larger size than the electrode.

13. A component-embedded board comprising:
a substrate;
an electronic component disposed over the substrate;
a conductive via formed in the substrate to be in contact with a bottom surface and a side surface of an electrode of the electronic component in a state where the electronic component is disposed over the substrate;
an adhesive layer formed over the substrate to cover the electronic component; and
a board laminated through the adhesive layer.

14. The component-embedded board according to claim 13, wherein the conductive via is arranged at a position corresponding to a corner portion of the bottom surface of the electrode, and is in contact with the bottom surface of the electrode, a first side surface of the electrode that intersects the bottom surface, and a second side surface of the electrode that intersects both the bottom surface and the first side surface.

15. The component-embedded board according to claim 13, further comprising:
a second conductive via formed in the substrate to be in contact with only the bottom surface of the electrode of the electronic component in a state where the electronic component is disposed over the substrate.

16. The component-embedded board according to claim 13, wherein a length of a portion of the conductive via deviated from an outer edge of the bottom surface of the electrode is 30% or more of a diameter of the conductive via on a component-mounting surface.

17. The component-embedded board according to claim 13, wherein the substrate includes, on a surface side opposite to a component-mounting surface, a conductive pad that is coupled to the conductive via and has a larger size than the electrode.
